(19) United States
(12) Patent Application Publication
(10) Pub. No.: US 2024/0149344 A1
(43) Pub. Date: May 9, 2024

(54) METAL PASTE FOR BONDING, AND METHOD FOR MANUFACTURING BONDED BODY

(71) Applicant: MITSUBISHI MATERIALS CORPORATION, Tokyo (JP)

(72) Inventors: Kohei Otogawa, Naka-shi (JP); Takuma Katase, Sanda-shi (JP)

(73) Assignee: MITSUBISHI MATERIALS CORPORATION, Tokyo (JP)

(21) Appl. No.: 18/284,338

(22) PCT Filed: Mar. 31, 2022
(86) PCT No.: PCT/JP2022/016454

§ 371 Date: Sep. 27, 2023

(30) Foreign Application Priority Data
Apr. 1, 2021 (JP) 2021-062770

(51) Int. Cl. B22F 9/24; B22F 1/142; B23K 35/30; B23K 35/36

(52) U.S. Cl. CPC B22F 9/24; B22F 1/142; B23K 35/3006; B23K 35/302; B23K 35/3618; B22F 2301/10; B22F 2301/255

(57) ABSTRACT

This metal paste for bonding includes a metal powder, a copper salt, an amine, and an alcohol, in which a ratio A/B of a weight A of Cu in the copper salt to a weight B of the metal powder is set to be in a range of 0.02 or more and 0.25 or less, the metal paste is in a paste form in a temperature range of 15° C. or higher and 35° C. or lower, a liquid phase is generated in a temperature raising process starting from 35° C., the liquid phase dissipates in the temperature raising process at a liquid phase generation temperature or higher, and a metal sintered body is formed at a liquid phase dissipation temperature or higher.

### TECHNICAL FIELD

The present invention relates to a metal paste for bonding used at a time of bonding members to each other and a method for producing a bonded body using the metal paste for bonding.

Priority is claimed on Japanese Patent Application No. 2021-062770, filed Apr. 1, 2021, the content of which is incorporated herein by reference.

### BACKGROUND ART

For instance, semiconductor devices called such as LEDs or power modules have a structure in which a semiconductor element is bonded on a circuit layer made from a metal member.

Here, in a case where electronic components such as semiconductor elements are bonded onto a circuit layer, a method using a solder material is widely used, for example, as disclosed in Patent Document 1.

In addition, Patent Document 2 proposes a technique for forming a plating film and an Sn-based solder layer, alloying these with each other by a heat treatment to form an alloy layer, and mounting electronic components on a substrate.

Furthermore, Patent Document 3 proposes a technique for bonding electronic components such as semiconductor elements onto a circuit by using a metal paste having a metal powder. In this metal paste, a bonding layer made from a conductive sintered body is formed and electronic components such as a semiconductor element are bonded onto a circuit through the bonding layer.

### CITATION LIST

### Patent Documents

[Patent Document 1]
Japanese Unexamined Patent Application, First Publication No. 2000-271782

[Patent Document 2]
Japanese Patent No. 6459656

[Patent Document 3]
Japanese Patent No. 6428339

### SUMMARY OF INVENTION

### Technical Problem

By the way, in a case where members are bonded together using a solder material as described in Patent Documents 1 and 2, a liquid phase is generated in a temperature raising process during the bonding. At this time, the relative positions between the members are adjusted by a surface tension of the liquid phase. That is, the relative positions between the members are self-aligned.

However, in a case where bonding is performed using a solder material, an intermetallic compound is generated in the bonding layer formed between the members, and there is thus a concern that the thermal conductivity may be relatively low. Furthermore, there is a concern that cracks easily occur in the bonding layer in a case of application of thermal cycles and the bonding reliability may be deteriorated.

Moreover, in a case where an electronic component such as a semiconductor element and a circuit layer are bonded through a solder material, a part of the solder melts at a time of being used in a high-temperature environment, and there is a concern that the bonding reliability between the electronic component such as a semiconductor element and the circuit layer may be deteriorated.

In particular, in recent years, the heat resistance of a semiconductor element itself has been improved and semiconductor devices are sometimes used in a high-temperature environment such as an engine room of an automobile. Therefore, in structures bonded with a solder material as in the related art, it has been difficult to deal with the problem.

On the other hand, in the metal paste disclosed in Patent Document 3, the thermal conductivity is excellent and the bonding reliability is also excellent from the viewpoint that the bonding layer is composed of a metal sintered body.

In addition, in a case where a bonding layer is formed of a metal sintered body, the bonding layer can be formed under relatively low-temperature conditions and the melting point of the bonding layer itself increases. Therefore, the bonding strength does not significantly decrease even in a high-temperature environment.

However, in a case where members are bonded to each other by using a metal paste, a liquid phase is not generated in the temperature raising process during bonding. Therefore, the relative positions between the members cannot be self-aligned.

The present invention has been made in view of the above-described circumstances, and has an object to provide a metal paste for bonding, which can generate a liquid phase in a temperature raising process during the bonding, can adjust the positioning of the relative positions between members by self-alignment, and is capable of forming a bonding layer made from a metal sintered body having excellent heat resistance and bonding strength; and a method for producing a bonded body using the metal paste for bonding.

### Solution to Problem

In order to accomplish the object, a metal paste for bonding of the present invention includes a metal powder, a copper salt, an amine, and an alcohol, in which a ratio A/B of a weight A of Cu in the copper salt to a weight B of the metal powder is set to be in a range of 0.02 or more and 0.25 or less, the metal paste is in a paste form in a temperature range of 15° C. or higher and 35° C. or lower, and a liquid phase is generated in a temperature raising process starting from 35° C., the liquid phase dissipates in the temperature raising process at a liquid phase generation temperature or higher, and a metal sintered body is formed at a liquid phase dissipation temperature or higher.

According to the metal paste for bonding having this configuration, the metal paste for bonding is configured such that the metal paste for bonding includes a metal powder, a copper salt, an amine, and an alcohol, and is in a paste form in the temperature range of 15° C. or higher and 35° C. or lower, and a liquid phase is generated in a temperature raising process starting from 35° C. Thus, it is possible to subject the metal paste for bonding to printing, dispensed coating, or pin transfer in a working environment at room temperature. On the other hand, a liquid phase is generated in the temperature raising process during the bonding, and the relative positions between the bonding members can be self-aligned. In addition, since the metal powder is included, even in a case where a liquid phase is generated, a distance can be secured between the members, and the bonding layer can thus be sufficiently formed.

Furthermore, since the present invention is configured such that the liquid phase dissipates at a liquid phase generation temperature or higher and a metal sintered body is formed at a liquid phase dissipation temperature or higher, the bonding strength does not decrease even in a high-temperature environment and it is possible to form a bonding layer which is excellent in the heat resistance and the bonding strength.

In addition, since the ratio A/B of the weight A of Cu in the copper salt to the weight B of the metal powder is set to be in the range of 0.02 or more and 0.25 or less, a liquid phase can be sufficiently formed in the temperature raising process, while the density of the metal sintered body after the sintering is sufficiently high such that a strong bonding strength can be realized.

Furthermore, since the alcohol is included, nano-sized copper particles can be generated by reducing the copper ions of the copper salt which has become the liquid phase in the temperature raising process during the bonding, and organic components forming a complex with the copper ion volatilize, which enables the liquid phase to reliably dissipate.

In addition, in the metal paste for bonding of the present invention, the metal powder is preferably one or two kinds of silver and copper.

In this case, since the metal powder is made from one or two kinds of silver and copper, it is possible to form a bonding layer which is particularly excellent in heat conduction.

Furthermore, in the metal paste for bonding of the present invention, the copper salt preferably includes a copper salt of an organic carboxylic acid.

In this case, since the copper salt is set to include the copper salt of an organic carboxylic acid, a metal complex can be reliably formed by adding the copper salt together with an amine, and the liquid phase can reliably appear in the temperature raising process during the bonding.

Furthermore, two or more kinds of copper salts may be included in the metal paste for bonding of the present invention.

In this case, with a use of a single copper salt, the mixture is not in a paste form in the temperature range of 15° C. or higher and 35° C. or lower, but by a combination of two or more kinds of copper salts, it is possible to form the mixture in a paste form in the temperature range of 15° C. or higher and 35° C. or lower. In addition, it is possible to adjust the liquid phase generation temperature and the liquid phase dissipation temperature depending on the combination of the copper salts.

In addition, in the metal paste for bonding of the present invention, the amine preferably includes a linear alkylamine.

In this case, since the amine is set to include the linear alkylamine, a metal complex can be reliably formed by incorporating the amine together with a copper salt, and the liquid phase can reliably appear in the temperature raising process during the bonding.

In addition, in the metal paste for bonding of the present invention, the amine may consist of two or more kinds of amines.

In this case, with a use of a single amine, the mixture is not in a paste form in the temperature range of 15° C. or higher and 35° C. or lower, but by a combination of two or more kinds of amines, it is possible to form the mixture in a paste form in the temperature range of 15° C. or higher and 35° C. or lower. In addition, it is possible to adjust the liquid phase generation temperature and the liquid phase dissipation temperature depending on the combination of the amines.

In addition, in the metal paste for bonding of the present invention, the alcohol may consist of two or more kinds of alcohols.

In this case, even in a case where the paste viscosity of a single alcohol is not optimal depending on the method of use, it is possible to adjust the paste viscosity to an appropriate value by combining two or more kinds of alcohols.

In addition, the metal paste for bonding of the present invention preferably further includes a silver salt in addition to the metal powder, the copper salt, the amine, and the alcohol.

In this case, the silver salt reacts with the amine to form a silver complex and the alcohol reduces the silver complex to generate nano-sized silver particles, whereby it is possible to further improve the bonding strength.

A method for producing a bonded body of the present invention is a method for producing a bonded body having a first member and a second member bonded to each other, the method including disposing the above-mentioned metal paste for bonding between the first member and the second member in a temperature range of 15° C. or higher and 35° C. or lower; raising a temperature in a state where the metal paste for bonding is disposed between the first member and the second member to generate a liquid phase between the first member and the second member; and further raising the temperature to a liquid phase generation temperature or higher to cause the liquid phase to dissipate and further raising the temperature to a liquid phase dissipation temperature or higher to form a metal sintered body, so that the first member and the second member are bonded to each other.

According to a method for producing a bonded body having the configuration, the above-mentioned metal paste for bonding is disposed between the first member and the second member in the temperature range of 15° C. or higher and 35° C. or lower, and the temperature is then raised to generate a liquid phase, so that the relative positions between the first member and the second member can be self-aligned by a surface tension of the liquid phase.

In addition, the temperature is raised to a liquid phase generation temperature or higher to cause the liquid phase to dissipate, and the temperature is further raised to a liquid phase dissipation temperature or higher to form a metal sintered body. Therefore, a bonding layer made from the metal sintered body can be formed, and a bonded body having excellent heat resistance and bonding strength can thus be produced.

### Advantageous Effects of Invention

According to the present invention, it is possible to provide a metal paste for bonding, which can generate a liquid phase in a temperature raising process during the bonding, can adjust the positioning of the relative positions between members by self-alignment, and is capable of forming a bonding layer made from a metal sintered body having excellent heat resistance and bonding strength; and a method for producing a bonded body using the metal paste for bonding.

### BRIEF DESCRIPTION OF DRAWINGS

FIG. 1 is a flowchart showing a method of bonding a bonded body, using the metal paste for bonding according to an embodiment of the present invention.

FIG. 2 is an explanatory view of a method of bonding a bonded body, using the metal paste for bonding according to an embodiment of the present invention.

FIG. 3 is an explanatory view of a mounting position of an Si chip and a method for confirming self-alignment in Examples.

FIG. 4 is an explanatory view of a method for evaluating a liquid phase generation temperature in Examples.

### DESCRIPTION OF EMBODIMENTS

Hereinafter, a metal paste for bonding and a method for producing a bonded body according to one embodiment of the present invention will be described.

The metal paste for bonding of the present embodiment is used in a case where the first member and the second member are bonded to produce a bonded body. For example, the metal paste for bonding is used in a case where a semiconductor element (second member) is bonded as an electronic component to a circuit layer (first member) of an insulating circuit substrate.

The metal paste for bonding of the present embodiment includes a metal powder, a copper salt, an amine, and an alcohol. Furthermore, the metal paste for bonding of the present embodiment may include a silver salt.

In addition, in the metal paste for bonding of the present embodiment, the ratio A/B of the weight A of Cu in the copper salt to the weight B of the metal powder is in the range of 0.02 or more and 0.25 or less.

Furthermore, the metal paste for bonding of the present embodiment is configured such that the metal paste for bonding is in a paste form in the temperature range of 15° C. or higher and 35° C. or lower, a liquid phase is generated in a temperature raising process starting from 35° C., the liquid phase dissipates at a liquid phase generation temperature or higher, and a metal sintered body is formed at a liquid phase dissipation temperature or higher.

In the present embodiment, since the metal paste for bonding includes a copper salt and an amine as described above, a metal complex (copper complex) is formed by mixing those. This metal complex becomes a paste in the temperature range of 15° C. or higher and 35° C. or lower, and is further heated to generate a liquid phase.

Here, in a case where the ratio A/B of the weight A of Cu in the copper salt to weight B of the metal powder is less than 0.02, the content of the copper salt becomes insufficient, and there is a concern that the liquid phase may not be sufficiently formed in the temperature raising process during the bonding and the self-alignment property may be impaired. On the other hand, in a case where the above-mentioned weight ratio A/B is more than 0.25, a liquid phase is excessively generated, the amount of volatilizing organic substances increases, and there is a concern that the density of the metal sintered body after the sintering may decrease and the bonding strength may decrease.

From this viewpoint, in the present embodiment, the ratio A/B of the weight A of Cu in the copper salt to the weight B of the metal powder is set to be in the range of 0.02 or more and 0.25 or less.

Incidentally, the above-mentioned weight ratio A/B is preferably 0.04 or more, and more preferably 0.06 or more. In addition, the above-mentioned weight ratio A/B is preferably 0.20 or less, and more preferably 0.15 or less.

Here, in the present embodiment, the metal powder is preferably one or two kinds of silver and copper.

In addition, the metal powder preferably has an average particle diameter in the range of 100 nm or more and 3 μm or less.

The copper salt may be added together with an amine to form a copper complex. In the present embodiment, the copper salt of an organic carboxylic acid is preferably used as the copper salt. Specifically, a Copper (II) acetate monohydrate, a copper citrate 2.5-hydrate, copper 2-ethylhexanoate, or the like can be used as the copper salt, and the Copper (II) acetate monohydrate is preferably used as the copper salt.

Furthermore, in the present embodiment, two or more kinds of copper salts may be included as the copper salt.

An amine may be added together with the copper salt to form a copper complex. In the present embodiment, the amine preferably includes a linear alkylamine. Specifically, dodecylamine, tetradecylamine, stearylamine, aminodecane, or the like can be used, and the dodecylamine is preferably used as the amine.

Furthermore, in the present embodiment, two or more kinds of amines may be contained as the amine.

As the alcohol, glycerin, α-terpineol, diethylene glycol (DEG), 2-ethyl-1,3-hexanediol (EHD), or the like can be used. In particular, the glycerin is preferably used.

Furthermore, in the present embodiment, two or more kinds of alcohols may be contained as the alcohol.

In addition, a silver salt may also be included as necessary. This silver salt may be added together with the amine to form a silver complex. In the present embodiment, examples of the silver salt include silver acetate, silver oxalate, silver propionate, silver myristate, and silver butyrate. In particular, the silver acetate is preferably used.

Here, the content of the metal powder is preferably in a range of 25% by mass or more and 75% by mass or less.

In addition, the content of the copper salt is preferably set to be in a range of 4% by mass or more and 16% by mass or less.

Furthermore, the content of the amine is preferably set to be in a range of 16% by mass or more and 54% by mass or less.

In addition, the content of the alcohol is preferably in a range of 1% by mass or more and 10% by mass or less.

Furthermore, in a case where a silver salt is included, the content of the silver salt is preferably in a range of 0.1% by mass or more and 12% by mass or less.

Incidentally, each content is a value in a case where the metal paste for bonding is regarded as 100% by mass.

The metal paste for bonding of the present embodiment can be produced by weighing the above-mentioned metal powder, copper salt, amine, and alcohol, and as necessary, a silver salt to have a predetermined blending, and mixing these.

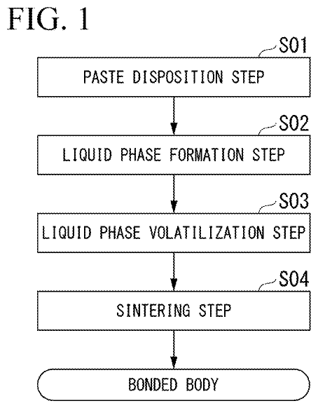

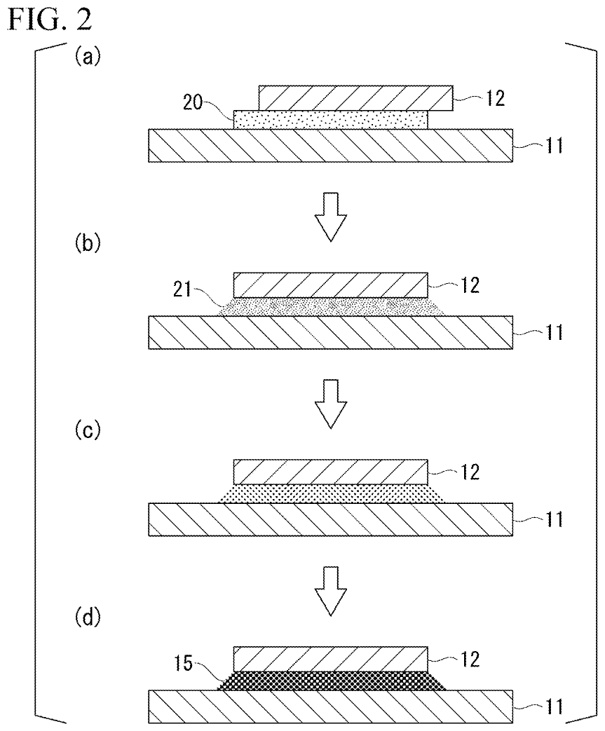

Next, a method for producing a bonded body using the metal paste for bonding of the present embodiment will be described with reference to FIGS. 1 and 2.

In the present embodiment, a bonded body 10 (semiconductor device), in which a first member 11 (circuit layer of an insulating circuit substrate) and a second member 12 (semiconductor element) are bonded through a bonding layer 15, is produced.

(Paste Disposition Step S01)

First, as shown in FIG. 2(a), the metal paste 20 for bonding of the present embodiment is disposed between the first member 11 and the second member 12.

In the present embodiment, the metal paste 20 for bonding is printed on a bonding surface of the first member 11 by screen printing. In addition, the coating thickness is preferably in the range of 20 lam or more and 500 atm or less.

(Liquid Phase Forming Step S02)

Next, the first member 11 and the second member 12 are laminated through the metal paste 20 for bonding and heated to a liquid phase generation temperature or higher.

In this case, in a temperature raising process starting from 35° C., a copper complex formed by the amine and the copper salt included in the metal paste 20 for bonding is liquefied, and a liquid phase 21 is generated between the first member 11 and the second member 12. As a result, the relative positions between the first member 11 and the second member 12 are self-aligned by a surface tension of the liquid phase 21, as shown in FIG. 2(b).

Here, the generation temperature for the liquid phase 21 is preferably in the range of higher than 35° C. and 100° C. or lower. The generation temperature for the liquid phase 21 is more preferably lower than 100° C.

In addition, in a case where the metal paste 20 for bonding includes a silver salt, a silver complex is formed by the silver salt and the amine.

(Liquid Phase Volatilization Step S03)

After the relative positions between the first member 11 and the second member 12 are self-aligned, the members are further heated and held at a constant temperature. The holding temperature may be in the range of 100° C. or higher and 200° C. or lower, and the holding time at the holding temperature may be in the range of 5 minutes or longer and 180 minutes or shorter. The holding temperature is more preferably lower than 200° C. In addition, it is preferable to set the temperature so that the liquid phase does not volatilize at once.

At this time, as shown in FIG. 2(c), the alcohol reduces the copper complex to generate nano-sized copper particles, while organic components (an acid component of the copper salt, the amine, and the alcohol) volatilize and most of the liquid phase 21 dissipates. In addition, in a case where the metal paste 20 for bonding includes a silver salt, a silver complex formed by the silver salt and the amine is reduced with the alcohol to generate nano-sized silver particles.

(Sintering Step S04)

After the organic component volatilizes, heating is further carried out. The heating temperature is set to a temperature higher than the liquid phase dissipation temperature. The heating temperature as mentioned herein may be in the range of 200° C. or higher and 400° C. or lower, and the holding time at the heating temperature may be in the range of 1 minute or longer and 90 minutes or shorter.

At this time, the sintering of the metal powder progresses, and as shown in FIG. 2(d), a bonding layer 15 made from a metal sintered body is formed.

Furthermore, in a case where the metal paste 20 for bonding includes a silver salt, nano-sized silver particles are generated to allow the sintering to proceed sufficiently, and it is possible to improve the bonding strength.

According to the metal paste for bonding according to the present embodiment, which has the configuration as described above, the metal paste for bonding includes a metal powder, a copper salt, an amine, and an alcohol, and is configured such that the metal paste for bonding is in a paste form in the temperature range of 15° C. or higher and 35° C. or lower, and is configured such that a liquid phase is generated in a temperature raising process starting from 35° C. Therefore, in a case where the metal paste 20 for bonding is disposed and bonded between the first member 11 and the second member 12, a liquid phase is generated between the first member 11 and the second member 12 in a temperature raising process during the bonding, and the relative positions between the first member 11 and the second member 12 can be self-aligned by a surface tension of this liquid phase. Furthermore, since the metal powder is included, a distance can be secured between the first member 11 and the second member 12 and the bonding layer 15 can be sufficiently formed even in a case where a liquid phase is generated.

Moreover, since the present embodiment is configured such that the liquid phase dissipates by raising the temperature to a liquid phase generation temperature or higher and a metal sintered body is formed by further raising the temperature to a liquid phase dissipation temperature or higher, a bonding layer having excellent heat resistance and bonding strength can be formed without generation of a liquid phase even in a case of being placed in the high-temperature environment again after sintering.

In addition, in the present embodiment, since the ratio A/B of the weight A of Cu in the copper salt to the weight B of the metal powder is set to be in the range of 0.02 or more, the content of the copper salt is ensured, a liquid phase can be sufficiently formed in a temperature raising process during the bonding and self-alignment can be performed. Furthermore, since the ratio A/B of the weight A of Cu in the copper salt to the weight B of the metal powder is set to be in the range of 0.25 or less, the amount of a liquid phase generated does not become excessive and the amount of volatilizing organic substances is suppressed, whereby the density of the metal sintered body after the sintering is sufficiently increased and a strong bonding strength can be realized.

Furthermore, since an alcohol is included in the present embodiment, nano-sized copper particles can be generated by reducing copper ions of the copper salt that has become a liquid phase in a temperature raising process during the bonding, and the organic components that have formed a complex with the copper ions volatilize, making it possible for the liquid phase to reliably dissipate.

Furthermore, in a case where the metal powder is one or two kinds of silver and copper in the metal paste for bonding of the present embodiment, the bonding layer 15 made from the metal sintered body can be formed and it is possible to form the bonding layer 15 which is particularly excellent in heat conduction.

Moreover, in a case where the copper salt includes a copper salt of an organic carboxylic acid in the metal paste for bonding of the present embodiment, a metal complex can be reliably formed by adding the copper salt together with an amine and the liquid phase can reliably appear in the temperature raising process during the bonding.

Furthermore, in a case where two or more kinds of copper salts are included as the copper salt in the metal paste for bonding of the present embodiment, the mixture is not in a paste form in the temperature range of 15° C. or higher and 35° C. or lower with a single copper salt, but it is possible to form the mixture in a paste form in the temperature range of 15° C. or higher and 35° C. or lower by combining the two or more kinds of copper salts. In addition, it is possible to adjust the liquid phase generation temperature and the liquid phase dissipation temperature depending on the combination.

In addition, in a case where the amine includes a linear alkylamine in the metal paste for bonding of the present embodiment, a metal complex can be reliably formed by adding the amine together with a copper salt and the liquid phase can reliably appear in the temperature raising process during the bonding.

Furthermore, in a case where two or more kinds of amines are included as the amine in the metal paste for bonding of the present embodiment, the mixture is not in a paste form in the temperature range of 15° C. or higher and 35° C. or lower with a single amine, but it is possible to form the mixture in a paste form in the temperature range of 15° C. or higher and 35° C. or lower by combining the two or more kinds of amines. In addition, it is possible to adjust the liquid phase generation temperature and the liquid phase dissipation temperature depending on the combination.

In addition, in the case where two or more kinds of alcohols are included as the alcohols in the metal paste for bonding of the present embodiment, the paste viscosity is not optimal depending on the using method with a single alcohol, but it is possible to adjust the paste viscosity to an appropriate value by combining the two or more kinds of alcohols.

Furthermore, in a case where a silver salt is further included in addition to the metal powder, the copper salt, the amine, and the alcohol in the metal paste for bonding of the present embodiment, the silver salt reacts with the amine to form a silver complex and the alcohol reduces this silver complex to generate nano-sized silver particles, whereby it is possible to further improve the bonding strength.

According to the method for producing the bonded body 10 of the present embodiment, the above-mentioned metal paste 20 for bonding is disposed between the first member 11 and the second member 12 in the temperature range of 15° C. or higher and 35° C. or lower, and the temperature is then raised to generate a liquid phase 21, so that the relative positions between the first member 11 and the second member 12 can be self-aligned by the surface tension of the liquid phase 21.

In addition, in the present embodiment, the temperature is raised to a liquid phase generation temperature or higher to cause the liquid phase to dissipate, and the temperature is further raised to a liquid phase dissipation temperature or higher to form a metal sintered body. Therefore, a bonding layer 15 made from the metal sintered body can be formed and a bonded body 10 having excellent heat resistance and bonding strength can thus be produced.

As described above, the embodiments of the present invention have been described, but the present invention is not limited thereto and can be suitably modified within a range not departing from the technical idea of the present invention.

For example, the present embodiments have been described with reference to an example where a semiconductor element (second member) as an electronic component is bonded to a circuit layer (first member) of an insulating circuit substrate, but the present invention is not limited thereto. The first member and the second member may be any of members that are bonded using the metal paste for bonding of the present invention.

### EXAMPLES

Hereinafter, the results of an evaluation test for evaluating the operations and effects of the metal paste for bonding and the method for producing a bonded body according to the present invention will be described.

### Example 1

First, a copper salt and an amine shown in Tables 1 and 2 were mixed at a ratio shown in Tables 1 and 2 to obtain a copper salt-amine mixture. Then, the copper salt-amine mixture was mixed with a metal powder and an alcohol shown in Tables 1 and 2 to obtain various mixtures according to Present Examples 1 to 19 and Comparative Examples 1 to 15.

In Tables 1 and 2, the metal particle diameters of the metal powders used are shown in parentheses.

In Comparative Example 11, Sn-3.0% Ag-0.5% Cu cream solder (manufactured by Senju Metal Industry Co., Ltd.) was used (designated as SnAg3Cu0.5 in Table 2).

In Comparative Example 12, the Cu core-and-Sn shell paste described in Example 1 of Japanese Patent No. 6645317 was used.

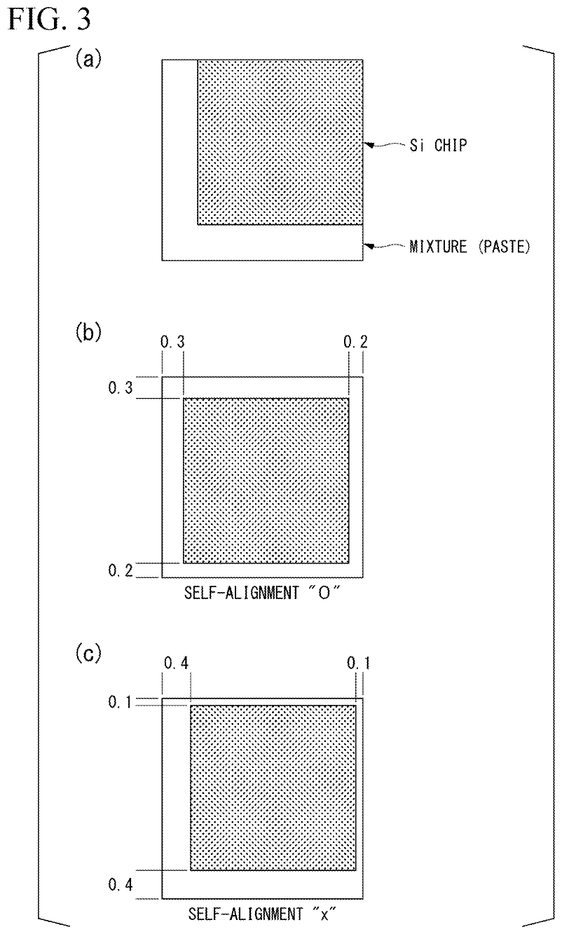

Next, the above-mentioned mixture was disposed (thickness: 50 μm and area: 3 mm square) on an oxygen-free copper plate having a thickness of 2 mm and metallized with Ag. A 400 μm-thick square Si chip (with an Au-metallized surface) having a side of 2.5 mm was mounted on the disposed mixture. As shown in FIG. 3(a), the mounting position was adjusted such that the two sides of the disposition surface of the mixture and the element surface coincided with each other. This was heated to form a bonding layer, and the oxygen-free copper plate and the Si chip were bonded.

The following items were evaluated for the obtained mixture and the bonding status.

Here, in Present Examples 1 to 19 and Comparative Examples 9, 10, 13, and 14, the temperature was raised from room temperature and held at a temperature for the liquid phase volatilization step shown in Table 3 and Table 4 for 60 minutes, the temperature was further raised and held at a temperature for the sintering step shown in Tables 3 and 4 for 15 minutes, and then the temperature was lowered to room temperature. Furthermore, the temperature increasing rate and the temperature decreasing rate were set to 2° C./min.

In Comparative Example 11 in which SnAgCu was used as the metal powder, the temperature was raised from room temperature and held at temperature for the liquid phase volatilization step shown in Table 4 for 3 minutes, the temperature was further raised and held at a temperature for the sintering step shown in Table 4 for 10 seconds, and then the temperature was lowered to room temperature. Furthermore, the temperature increasing rate and the temperature decreasing rate were set to 30° C./min. In addition, the liquid phase generation temperature was taken as the melting temperature of SnAgCu, and the liquid phase dissipation temperature was taken as the volatilization temperature of the flux.

In Comparative Example 12 in which Cu core-and-Sn shell was used as the metal powder, the temperature was raised from room temperature and held at a temperature for the liquid phase volatilization step shown in Table 4 for 3 minutes, the temperature was further raised and held at a temperature for the sintering step shown in Table 4 for 10 seconds, and then the temperature was lowered to room temperature. Furthermore, the temperature increasing rate and the temperature decreasing rate were set to 30° C./min. In addition, the liquid phase generation temperature was taken as a melting point of Sn, and the liquid phase dissipation temperature was taken as the volatilization temperature of the flux.

(Properties at 15° C. to 35° C.)

Each of the obtained mixtures was visually confirmed, and in a case where a powdery residue was confirmed (a case where the mixture was in a so-called dry state), the mixture was defined as being in a “powder form”. For each mixture other than the mixture which was in the “powder form”, the viscosity was measured by a rheometer (DHR-3 manufactured by TA Instruments) while the measurement temperatures were set to 15° C. and 35° C., and the shear rate was set to 10 (1/s). A mixture having a viscosity of 10 Pas or more and 500 Pas or less at either of 15° C. and 35° C. was regarded as a “paste form”, and a mixture having a viscosity of less than 10 Pas as measured at either of the temperatures was regarded as a “liquid form”.

(Presence or Absence of Liquid Phase Generation/Liquid Phase Generation Temperature)

The measurement was carried out using thermal weight differential thermal analysis (TG-DTA) (NETZSCH Analyzing & Testing, STA-2500 Regulus). For each of the obtained mixtures, differential thermal analysis was performed from 25° C. to 500° C. in a nitrogen atmosphere (temperature increasing rate of 10° C./min). In a case where no weight reduction was observed on the TG curve and an endothermic peak was observed on the DTA curve, it was determined that a liquid phase was generated.

In Tables 3 and 4, those determined to have the generation of the liquid phase were designated as “Present”, those determined to have no generation of a liquid phase and remain in a liquid state were designated as “Remaining as liquid”, and those determined to have no generation of a liquid phase was designated as “Absent”.

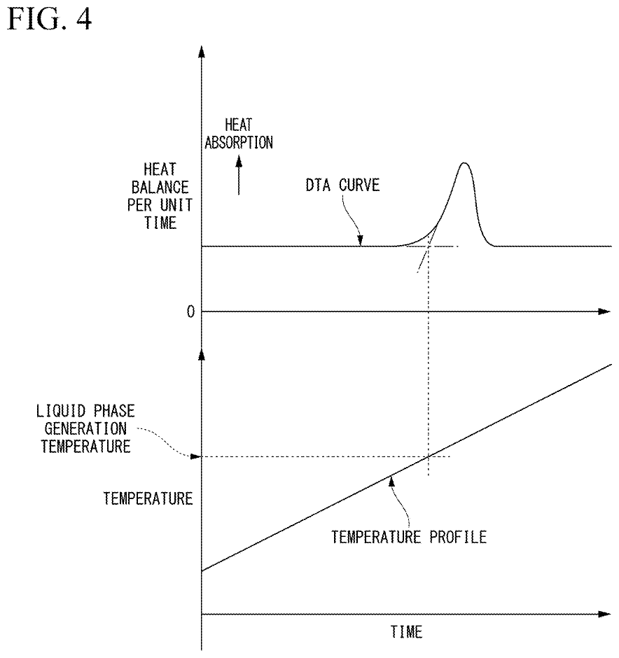

The liquid phase generation temperature was defined as a temperature of a point at which a tangential line drawn from the peak of the DTA curve toward the low temperature part (low temperature side) intersects the extension line of the flat portion of the DTA curve, as shown in FIG. 4.

(Liquid Phase Dissipation/Liquid Phase Dissipation Temperature)

The measurement was carried out up to 500° C. using the same measuring device and conditions as in the case where the presence or absence of the liquid phase generation was determined. In a case where a weight reduction equal to or more than the amount of the alcohol added or the amount of the flux added up to 300° C. was observed on the TG curve, it was determined that the liquid phase dissipated and designated as “A”, and in a case where the weight reduction was less than the amount of the alcohol added or the amount of the flux added, it was determined that the liquid phase remained and designated as “B”.

The liquid phase dissipation temperature was defined as a temperature at which a tangential line at the time of weight reduction intersects an extension line of the straight line in a steady state where the weight reduction has ended on the TG curve.

(Self-Alignment)

After performing the sintering, a distance between a bonding material and the adjacent side of the chip was measured. In a case where there was a distance of 0.2 mm or more on all four sides as shown in FIG. 3(b), it was designated as “A”, indicating that there was alignability, and in a case where even one side had a distance of less than 0.2 mm as shown in FIG. 3(c), it was designated as “B”, indicating that there was no alignability.

(Shear Strength)

The bonding strength was measured using a shear strength evaluation tester (MFM 1500HF manufactured by TRY PRECISION).

Specifically, the measurement of the bonding strength was performed by horizontally fixing the oxygen-free copper plate of the bonded body, pressing the Si chip of the bonded body from the side in the horizontal direction by means of a shear tool at a position 50 μm above the surface (upper face) of the bonding layer, and then measuring the strength in a case were the Si chip was fractured. Incidentally, the moving speed of the shear tool was set to 0.1 mm/sec. The strength test was performed three times per condition, and the arithmetic mean value of those was used as the measured value of the bonding strength.

(Evaluation of Heat Resistance)

A thermal shock test was carried out for 100 cycles with one cycle being a process in which the sample after the sintering was heated at 175° C. for 15 minutes using a thermal shock tester (TSE-11-A manufactured by Espec Co., Ltd.), then cooled for 15 minutes by lowering the temperature to −40° C., and then further heated to 175° C.

An image was captured to confirm a portion where the oxygen-free copper plate and the Si chip were bonded in the bonding layer, using an ultrasonic imaging device (FSP8V, manufactured by Hitachi Power Solutions Co., Ltd.). A transducer (probe) used has a frequency of 140 MHz. An area peeled from the captured image was determined, and a case where the peeled area was less than 10% of the chip area was designated as “A” and a case where the peeled area was 10% or more was designated as “B”. Incidentally, the image obtained by the ultrasonic imaging device, a portion in which the Si chip and the oxygen-free copper plate are peeled looks white, and a portion in which the Si chip and the oxygen-free copper plate are bonded to each other looks gray.

TABLE 1

| | | | | | | | Weight of | | | | |
|---|---|---|---|---|---|---|---|---|---|---|---|
| | | | | Copper salt | | | copper in | | | | |
| | | | | | | Pro- | copper | | | | |
| | | Metal powder | | | | portion | salt/ | Amine | | Alcohol | |
| | | | Content | | Content | of copper | weight | | Content | | Content |
| | | | (% by | | (% by | (% by | of metal | | (% by | | (% by |
| | | Material | mass) | Material | mass) | mass) | powder | Material | mass) | Material | mass) |
| Present | 1 | Ag (100 nm) | 50 | Copper (II) acetate | 10 | 31.8 | 0.06 | Dodecylamine | 35 | Glycerin | 5 |
| Ex- | | | | monohydrate | | | | | | | |
| ample | 2 | Ag (100 nm) | 50 | Copper (II) acetate | 10 | 31.8 | 0.06 | Dodecylamine | 35 | Glycerin | 5 |
| | | | | monohydrate | | | | | | | |
| | 3 | Ag (100 nm) | 50 | Copper 2-ethylhexanoate | 13 | 18.1 | 0.05 | Tetradecylamine | 32 | Glycerin | 5 |
| | 4 | Ag (100 nm) | 50 | Copper 2-ethylhexanoate | 11 | 18.1 | 0.04 | Stearylamine | 34 | Glycerin | 5 |
| | 5 | Ag (100 nm) | 50 | Copper 2-ethylhexanoate | 12 | 18.1 | 0.04 | Aminodecane | 5 | Glycerin | 5 |
| | | | | | | | | Stearylamine | 28 | | |
| | 6 | Ag (100 nm) | 50 | Copper (II) citrate 2.5- | 4 | 24.0 | 0.06 | Aminodecane | 7 | Glycerin | 5 |
| | | | | hydrate | | | | | | | |
| | | | | Copper 2-ethylhexanoate | 8 | | | Stearylamine | 26 | | |
| | 7 | Ag (100 nm) | 50 | Copper (II) citrate 2.5- | 4 | 24.0 | 0.06 | Dodecylamine | 33 | Glycerin | 5 |
| | | | | hydrate | | | | | | | |
| | | | | Copper 2-ethylhexanoate | 8 | | | | | | |
| | 8 | Ag (100 nm) | 50 | Copper (II) acetate | 10 | 31.8 | 0.06 | Dodecylamine | 35 | α- | 5 |
| | | | | monohydrate | | | | | | Terpincol | |
| | 9 | Ag (100 nm) | 50 | Copper (II) acetate | 10 | 31.8 | 0.06 | Dodecylamine | 35 | EHD | 5 |
| | | | | monohydrate | | | | | | | |
| | 10 | Ag (100 nm) | 50 | Copper (II) acetate | 10 | 31.8 | 0.06 | Dodecylamine | 35 | DEG | 5 |
| | | | | monohydrate | | | | | | | |
| | 11 | Ag (100 nm) | 75 | Copper (II) acetate | 4 | 31.8 | 0.02 | Dodecylamine | 16 | Glycerin | 5 |
| | | | | monohydrate | | | | | | | |
| | 12 | Ag (100 nm) | 25 | Copper (II) acetate | 16 | 31.8 | 0.20 | Dodecylamine | 54 | Glycerin | 5 |
| | | | | monohydrate | | | | | | | |
| | 13 | Cu (100 nm) | 50 | Copper (II) acetate | 10 | 31.8 | 0.06 | Dodecylamine | 35 | Glycerin | 5 |
| | | | | monohydrate | | | | | | | |
| | 14 | Ag (3 μm) | 50 | Copper (II) acetate | 10 | 31.8 | 0.06 | Dodecylamine | 35 | Glycerin | 5 |
| | | | | monohydrate | | | | | | | |
| | 15 | Cu (3 μm) | 50 | Copper (II) acetate | 10 | 31.8 | 0.06 | Dodecylamine | 35 | Glycerin | 5 |
| | | | | monohydrate | | | | | | | |
| | 16 | Ag (100 nm) | 50 | Copper 2-ethylhexanoate | 13 | 18.1 | 0.05 | Tetradecylamine | 27 | Glycerin | 10 |
| | 17 | Ag (100 nm) | 50 | Copper 2-ethylhexanoate | 12 | 18.1 | 0.04 | Aminodecane | 9 | Glycerin | 1 |
| | | | | | | | | Stearylamine | 28 | | |
| | 18 | Ag (100 nm) | 50 | Copper 2-ethylhexanoate | 13 | 18.1 | 0.05 | Tetradecylamine | 27 | α- | 5 |
| | | | | | | | | | | Terpincol | |
| | | | | | | | | | | DEG | 5 |
| | 19 | Ag (100 nm) | 25 | Copper (II) acetate | 10 | 31.8 | 0.06 | Dodecylamine | 35 | Glycerin | 5 |
| | | Cu (3 μm) | 25 | monohydrate | | | | | | | |

TABLE 2

| | | | | | | | Weight of | | | | |
|---|---|---|---|---|---|---|---|---|---|---|---|
| | | | | Copper salt | | | copper in | | | | |
| | | | | | | Pro- | copper | | | | |
| | | Metal powder | | | | portion | salt/ | Amine | | Alcohol | |
| | | | Content | | Content | of copper | weight | | Content | | Content |
| | | | (% by | | (% by | (% by | of metal | | (% by | | (% by |
| | | Material | mass) | Material | mass) | mass | powder | Material | mass) | Material | mass) |
| Com- | 1 | Ag (100 nm) | 50 | Copper (II) acetate | 9 | 31.8 | 0.05 | Tetradecylamine | 36 | Glycerin | 5 |
| parative | | | | monohydrate | | | | | | | |
| Example | 2 | Ag (100 nm) | 50 | Copper (Il) acetate | 7 | 31.8 | 0.04 | Stearylamine | 38 | Glycerin | 5 |
| | | | | monohydrate | | | | | | | |
| | 3 | Ag (100 nm) | 50 | Copper (II) citrate 2.5-hydrate | 10 | 35.3 | 0.07 | Aminodecane | 35 | Glycerin | 5 |
| | 4 | Ag (100 nm) | 50 | Copper (II) citrate 2.5-hydrate | 9 | 35.3 | 0.06 | Dodecylamine | 36 | Glycerin | 5 |
| | 5 | Ag (100 nm) | 50 | Copper (II) citrate 2.5-hydrate | 8 | 35.3 | 0.06 | Tetradecylamine | 37 | Glycerin | 5 |
| | 6 | Ag (100 nm) | 50 | Copper (II) citrate 2.5-hydrate | 6 | 35.3 | 0.05 | Stearylamine | 39 | Glycerin | 5 |
| | 7 | Ag (100 nm) | 50 | Copper 2-ethylhexanoate | 16 | 18.1 | 0.06 | Aminodecane | 29 | Glycerin | 5 |
| | 8 | Ag (100 nm) | 50 | Copper 2-ethylhexanoate | 14 | 18.1 | 0.05 | Dodecylamine | 31 | Glycerin | 5 |
| | 9 | Ag (100 nm) | 80 | Copper (II) acetate | 3 | 31.8 | 0.01 | Dodecylamine | 12 | Glycerin | 5 |
| | | | | monohydrate | | | | | | | |
| | 10 | Ag (100 nm) | 20 | Copper (II) acetate | 17 | 31.8 | 0.27 | Dodecylamine | 58 | Glycerin | 5 |
| | | | | monohydrate | | | | | | | |
| | 11 | SnAg3Cu0.5 | 88 | — | — | — | — | — | — | Flux | 12 |
| | 12 | Cu core-and- | 88 | — | — | — | — | — | — | Flux | 12 |
| | | Sn shell | | | | | | | | | |
| | 13 | Ag (100 nm) | 80 | — | — | — | — | Octylamine | 15 | Glycerin | 5 |
| | 14 | Ag (100 nm) | 50 | Copper (II) acetate | 10 | 32 | 0.06 | Dodecylamine | 35 | Glycerin | 5 |
| | | | | monohydrate | | | | | | | |
| | 15 | Ag (100 nm) | 50 | Copper (II) acetate | 11 | 32 | 0.07 | Aminodecane | 34 | Glycerin | 5 |
| | | | | monohydrate | | | | | | | |

TABLE 3

| | | Heating conditions | | | | | | | | | |
|---|---|---|---|---|---|---|---|---|---|---|---|
| | | | | | | | Temperature | | | | |
| | | | Presence or | Liquid | Liquid | | for liquid | | | | |
| | | | absence of | phase | phase | Dissipation of | phase | Temperature | Evaluation | | |
| | | Properties at | liquid | generation | dissipation | liquid phase | volatilization | for sintering | | | Shear |
| | | 15° C. to | phase | temperature | temperature | up to | step | step | Self- | Heat | strength |
| | | 35° C. | generation | (° C.) | (° C.) | 300° C. | (° C.) | (° C.) | alignment | resistance | (MPa) |
| Present | 1 | Paste form | Present | 60 | 227 | A | 130 | 300 | A | A | 11 |
| Example | 2 | Paste form | Present | 60 | 227 | A | 130 | 350 | A | A | 16 |
| | 3 | Paste form | Present | 35 | 234 | A | 140 | 350 | A | A | 13 |
| | 4 | Paste form | Present | 43 | 277 | A | 180 | 350 | A | A | 12 |
| | 5 | Paste form | Present | 35 | 272 | A | 140 | 350 | A | A | 15 |
| | 6 | Paste form | Present | 35 | 274 | A | 140 | 350 | A | A | 14 |
| | 7 | Paste form | Present | 35 | 237 | A | 140 | 350 | A | A | 15 |
| | 8 | Paste form | Present | 60 | 203 | A | 115 | 350 | A | A | 12 |
| | 9 | Paste form | Present | 60 | 210 | A | 120 | 350 | A | A | 11 |
| | 10 | Paste form | Present | 60 | 212 | A | 120 | 350 | A | A | 13 |
| | 11 | Paste form | Present | 60 | 227 | A | 130 | 350 | A | A | 14 |
| | 12 | Paste form | Present | 60 | 227 | A | 130 | 350 | A | A | 10 |
| | 13 | Paste form | Present | 60 | 227 | A | 130 | 350 | A | A | 14 |
| | 14 | Paste form | Present | 60 | 227 | A | 130 | 350 | A | A | 14 |
| | 15 | Paste form | Present | 60 | 227 | A | 130 | 350 | A | A | 13 |
| | 16 | Paste form | Present | 35 | 234 | A | 140 | 350 | A | A | 12 |
| | 17 | Paste form | Present | 35 | 272 | A | 140 | 350 | A | A | 14 |
| | 18 | Paste form | Present | 35 | 211 | A | 140 | 350 | A | A | 13 |
| | 19 | Paste form | Present | 60 | 227 | A | 130 | 350 | A | A | 14 |

TABLE 4

| | | Heating conditions | | | | | | | | | |
|---|---|---|---|---|---|---|---|---|---|---|---|
| | | | | | | | Temperature | Tem- | | | |
| | | | Presence or | Liquid | | Dissipation | for liquid | perature | | | |
| | | | absence of | phase | | of liquid | phase | for | Evaluation | | |
| | | Properties at | liquid | generation | Liquid phase | phase | volatilization | sintering | | | Shear |
| | | 15° C. to | phase | temperature | dissipation | up to | step | step | Self- | Heat | strength |
| | | 35° C. | generation | (° C.) | temperature | 300° C. | (° C.) | (° C.) | alignment | resistance | (MPa) |
| Comparative | 1 | Powder form | Present | 67 | 229 | A | — | — | Not printable | | |
| Example | 2 | Powder form | Present | 80 | 274 | A | — | — | Not printable | | |
| | 3 | Liquid form | Liquid form | — | 252 | A | — | — | Not printable | | |
| | | | as it is | | | | | | | | |
| | 4 | Powder form | Present | — | 257 | A | — | — | Not printable | | |
| | 5 | Powder form | Present | — | 267 | A | — | — | Not printable | | |
| | 6 | Powder form | Present | 57 | 274 | A | — | — | Not printable | | |
| | 7 | Liquid form | Liquid form | — | 227 | A | — | — | Not printable | | |
| | | | as it is | | | | | | | | |
| | 8 | Liquid form | Liquid form | — | 224 | A | — | — | Not printable | | |
| | | | as it is | | | | | | | | |
| | 9 | Paste form | Present | 60 | 227 | A | 130 | 350 | B | A | 12 |
| | 10 | Paste form | Present | 60 | 227 | A | 130 | 350 | A | B | 4 |
| | 11 | Paste form | Present | 220 | 180 | B | 150 | 250 | A | B | 22 |
| | 12 | Paste form | Present | 232 | 200 | A | 160 | 300 | A | B | 28 |
| | 13 | Paste form | Absence | — | 210 | Liquid phase | 100 | 250 | B | A | 19 |
| | | | | | | not present | | | | | |
| | 14 | Paste form | Present | 60 | 227 | A | 130 | 200 | A | A | 2 |

| | | | | | | | | |
|---|---|---|---|---|---|---|---|---|
| 15 | Liquid form | Liquid form | — | 227 | A | — | — | Not printable |
| | | as it is | | | | | | |

In Comparative Examples 1, 2, and 4 to 6, the product was in a powder form in the temperature range of 15° C. or higher and 35° C. or lower, and the mixture could not be printed on the oxygen-free copper plate. Therefore, the self-alignment, the heat resistance, and the shear strength were not evaluated.

In Comparative Examples 3, 7, 8, and 15, the product was in the form of a liquid in the temperature range of 15° C. or higher and 35° C. or lower, and the mixture could not be printed on the oxygen-free copper plate. Therefore, the self-alignment, the heat resistance, and the shear strength were not evaluated.

In Comparative Example 9, the ratio A/B of the weight A of Cu in the copper salt to the weight B of the metal powder was set to be 0.01, the content of the copper salt was insufficient, the liquid phase was not sufficiently formed, and the self-alignment was “B”.

In Comparative Example 10, the ratio A/B of the weight A of Cu in the copper salt to the weight B of the metal powder B was set to be 0.27, the density of the metal sintered body of the bonding layer was low due to a large amount of the organic substance that had volatilized, and the bonding strength (shear strength) was low.

In Comparative Examples 11 and 12, Cu—Sn-based solder materials were used and the heat resistance was insufficient.

In Comparative Example 13, an Ag paste having no copper salt was used, no liquid phase was generated during the temperature raising process, and the self-alignment was “B”.

In Comparative Example 14, the temperature for the sintering step was lower than the liquid phase dissipation temperature, the organic components remained inside the bonding layer made from the metal sintered body, and the bonding strength was decreased.

On the other hand, in Present Examples 1 to 19, the metal paste for bonding is considered to include a metal powder, a copper salt, and an amine and is in a paste form in the temperature range of 15° C. or higher and 35° C. or lower, in which a liquid phase is generated in a temperature raising process starting from 35° C., a liquid phase dissipates in the temperature raising process at a liquid phase generation temperature or higher and a metal sintered body is formed at a liquid phase dissipation temperature or higher. Thus, the self-alignment was “A”, and the heat resistance and the bonding strength were excellent.

From the above, according to Present Examples, it was confirmed that it is possible to provide a metal paste for bonding, which causes generation of a liquid phase in a temperature raising process during the bonding, enables the positioning adjustment of the relative positions between members by self-alignment, and makes it possible to form a bonding layer having excellent heat resistance and bonding strength; and a method for producing a bonded body.

### Example 2

A product obtained by adding 4% by mass of a silver salt (silver acetate) to the metal paste for bonding of Present Example 2 shown in Table 1 was designated as Present Example 20.

Next, an oxygen-free copper plate (hereinafter an Ag-metallized copper plate) having a thickness of 2 mm, the outermost surface of which had been metallized with Ag, was prepared.

The metal pastes for bonding of Present Example 2 and Present Example 20 were disposed on this Ag-metallized layer (thickness: 100 μm, area: 3 mm square). A square Si chip (surface obtained by metallizing Au) having a thickness of 2.5 mm and a side of 2.5 mm was mounted on the disposed mixture. This was heated to form a bonding layer, and the oxygen-free copper plate and the Si chip were bonded. Here, the heating temperature and the holding time of the liquid phase volatilization step and the heating temperature and the holding time of the sintering step were set as the conditions shown in Table 5.

Then, the shear strength was measured in the same procedure as in Example 1. The measurement results are shown in Table 5.

TABLE 5

| | | Liquid phase volatilization step | | | Sintering step | | | |
|---|---|---|---|---|---|---|---|---|
| | | | Temperature | Time | | Temperature | Time | Shear strength |
| | Metal paste for bonding | Atmosphere | (° C.) | (min) | Atmosphere | (° C.) | (min) | (MPa) |
| Test 1 | Present Example 2 (Silver | N₂ | 130 | 60 | N₂ | 350 | 15 | 5 |
| | salt not used) | | | | | | | |
| Test 2 | Present Example 20 (Silver | N₂ | 125 | 60 | N₂ | 350 | 15 | 33 |
| | salt added) | | | | | | | |

As shown in Table 5, it was confirmed that in the metal paste for bonding of Present Example 20, to which a silver salt was added, the shear strength is improved, as compared with the metal paste for bonding of Present Example 2, to which a silver salt was not added.

1. A metal paste for bonding, comprising:
a metal powder;
a copper salt;
an amine; and
an alcohol,
wherein a ratio A/B of a weight A of Cu in the copper salt to a weight B of the metal powder is set to be in a range of 0.02 or more and 0.25 or less,
the metal paste is in a paste form in a temperature range of 15° C. or higher and 35° C. or lower, and
a liquid phase is generated in a temperature raising process starting from 35° C., the liquid phase dissipates in the temperature raising process at a liquid phase generation temperature or higher, and a metal sintered body is formed at a liquid phase dissipation temperature or higher.

2. The metal paste for bonding according to claim 1,
wherein the metal powder is one or two kinds of silver and copper.

3. The metal paste for bonding according to claim 1,
wherein the copper salt includes a copper salt of an organic carboxylic acid.

4. The metal paste for bonding according to claim 1,
wherein the copper salt consists of two or more kinds of copper salts.

5. The metal paste for bonding according to claim 1,
wherein the amine includes a linear alkylamine.

6. The metal paste for bonding according to claim 1,
wherein the amine consists of two or more kinds of amines.

7. The metal paste for bonding according to claim 1,
wherein the alcohol consists of two or more kinds of alcohols.

8. The metal paste for bonding according to claim 1, further comprising a silver salt.

9. A method for producing a bonded body having a first member and a second member bonded to each other, the method comprising:
disposing the metal paste for bonding according to claim 1 between the first member and the second member in a temperature range of 15° C. or higher and 35° C. or lower;
raising a temperature in a state where the metal paste for bonding is disposed between the first member and the second member to generate a liquid phase between the first member and the second member; and
further raising the temperature to a liquid phase generation temperature or higher to cause the liquid phase to dissipate, and further raising the temperature to a liquid phase dissipation temperature or higher to form a metal sintered body, so that the first member and the second member are bonded to each other.
